(19) United States
(12) Patent Application Publication
(10) Pub. No.: US 2026/0227078 A1
(43) Pub. Date: Aug. 6, 2026

(54) MODULAR, SOLID STATE HEATING SYSTEMHEATING AND METHOD FOR HEATING USING THE MODULAR SOLID STATE HEATING SYSTEM

(71) Applicants: SWELLIN INVEST AB, Sundsvall (SE); SVENSKA FLYGTEKNISKA INSTITUTES AB, SPÅNGA (SE)

(72) Inventors: Lars Wallin, Sundsvall (SE); Tomas Mellin, Spånga (SE)

(21) Appl. No.: 19/155,514

(22) PCT Filed: Feb. 23, 2024
(86) PCT No.: PCT/EP2024/054726

§ 371 Date: Aug. 11, 2025

(30) Foreign Application Priority Data
Feb. 24, 2023 (EP) 23158424.4

(51) Int. Cl. F24D 12/00

(52) U.S. Cl. CPC F24D 12/00; F24D 2200/08

(57) ABSTRACT

A system for providing heating from a solid state thermal energy generator computing module inside a module housing includes a computing unit with processors, a fan and a heat exchanger. The computing unit provide computing capacity and waste thermal energy. The module housing includes an inner closed circuit for recirculation of an internal cooling agent. The heat energy in the inner closed circuit is exchanged to a fluid medium in an outer circuit via a heat exchanger. The heated fluid medium is supplied via a conduit, to be stored in a heating storage system or be dumped. The invention also relates to a method for providing heating from a solid state thermal energy generator, to provide heating in the vicinity of the solid state thermal energy generator, while providing computing capacity.

### CROSS-REFERENCE TO RELATED APPLICATIONS

The instant application is a U.S. National Stage application of and claims priority to PCT/EP2024/054726, filed on Feb. 23, 2024, which is a PCT application of and claims priority to EP Application No. 23158424.4, filed on Feb. 24, 2023, the subject matter of both aforementioned applications is hereby incorporated by reference in their entireties.

### TECHNICAL FIELD

The invention relates to a modular system for providing heat capacity/heating to customers from solid state technology, wherein heating is generated by at least one solid state thermal generator/thermal energy generator, situated at an optimal distance to the customers. The system provides computing capacity by the solid state thermal energy generator while heating is generated.

The invention also relates to a method for providing heating to customers in the system.

The invention also relates to a use of heating from at least one solid state thermal energy generator, to provide heating to customers in the vicinity of the solid state thermal energy generator, while providing computing capacity.

### BACKGROUND

The invention is advantageously used for providing heating from a solid state thermal energy generator to customers at an optimal distance to the solid state thermal energy generator, while the solid state thermal energy generator provides computing capacity at the same time.

Traditional industries and other commercial activities that require a high amount of heating in their processes are often dependent on specific logistical solutions for energy transportation. Fossil fuel and bio fuel require transportation and storage of the fuel. Hence, these logistical solutions result in that capital in fuel storage and infrastructure is locked up as well as business risks due to environmental concerns.

Electrical energy is much easier to transport but suffers from high exergy loss when used for heating. Further, customers in traditional industries and other commercial activities need primarily that a total requirement of heating can be provided, that a sufficient temperature can be delivered by heating and that the requirement for heating provided can be scheduled during the year.

Consequently, there may be a lot of different criteria that need to be considered when providing heating generated from electricity.

The following definitions are used in the description and the appended claims:
Computing Capacity is the digital processing capacity that can be delivered globally
Heating is the thermal heat generated by converting electrical energy into heat in the Solid State thermal energy generator (SSTG)
Electrical Energy Supply is the green source or zero carbon footprint energy supply
Circular Components are systems that can connect to the heating and reuse the energy
Heating Management Systems means the control system that regulates the provision of Heating
A solid state thermal energy generator (SSTG) is a computing device capable of performing digital processing and transferring electrical energy into thermal energy which can be collected by a heat exchanger and subsequently can be used for heating or cooling A desire is to provide heating (or cooling) from solid state technology, such as a solid state thermal energy generator, to customers close to the solid state thermal energy generator thereby providing heating as well as computing capacity.

Further, it is a desire to provide a system that is cost efficient and able to achieve large cost savings in the use of electric energy for heating buildings, industries, and other facilities in commercial activities.

Yet a further desire is that the computing work provided in the solid state thermal energy generator can be sold, leased, rented, or put on the market in other ways, or, alternatively, be dumped.

A further desire is that the computing capacity can be conveyed via the internet or other transportation protocols.

There is also a desire to eliminate the use of the logistic solutions for energy transportation and chemical fuels in traditional industries and other commercial activities.

U.S. Pat. No. 9,554,491B1 discloses a data center cooling system which includes a cooling liquid supply conduit fluidly coupled between a cooling plant and an air-to-liquid heat exchanger positioned to receive a heated airflow from one or more racks. At least one rack supports a plurality of heat-generating electronic devices. The system further includes a cooling liquid return conduit fluidly coupled between the cooling plant and the air-to-liquid heat exchanger; and a heat transfer module thermally coupled to the cooling liquid supply and return conduits between the cooling plant and the air-to-liquid heat exchanger. The heat transfer module includes a cold side and a warm side, with the cold side thermally coupled to the cooling liquid supply conduit to transfer heat from a flow of a cooling liquid in the cooling liquid supply conduit to the warm side of the heat transfer module, and the warm side including a heat sink.

However, U.S. Pat. No. 9,554,491B1 describes mainly a cooling system for a data center and does not disclose the means for providing heating from solid state technology, such as a solid state thermal energy generator, to customers in the vicinity of the solid state thermal energy generator while the solid state thermal energy generator provides computing capacity at the same time.

### SUMMARY

An object of the invention is to improve the use of heating provided by solid state technology when providing computing capacity.

Another object of the invention is to provide heating from solid state technology, such as a solid state thermal energy generator, to customers in the vicinity of a solid state thermal energy generator wherein the solid state thermal energy generator also provides computing capacity to customers.

A further object is to be able to provide a system that is cost efficient and able to achieve large cost savings in the use of electric energy for heating buildings, industries, residential buildings and other facilities.

Yet a further object is that the computing capacity provided in the solid state thermal energy generator can be sold, leased, rented, or put on the market in other ways, or, alternatively, be dumped to the environment.

Further, it is a desire to provide a computing capacity that can be delivered globally via internet or other transportation protocols.

The objects are achieved by a system according to claim 1. Thus, the objects are achieved by a system for providing heating to customers from a solid state thermal energy generator with at least one module comprising a computing unit, comprising computing processors which generate waste heat when in use and a heat exchanger unit. The computing unit provides computing capacity and a heating capacity which generated by the waste heat from the processors. The heat energy of the waste heat is exchanged to a fluid medium in an outer circuit via the heat exchanger unit that is positioned to receive the heat energy in the inner closed circuit, and the heated fluid medium is supplied via a conduit/which may be part of the outer circuit) to customers for immediate consumption, to be stored in a heating storage system or be dumped.

As a result, an improved use of heating can be provided by a solid state thermal energy generator when providing computing capacity. Thanks to the fact that heating from the solid state thermal energy generator is provided to customers, at the same time as the solid state thermal energy generator provides computing capacity to customers, an energy efficient system and a cost saving improvement for providing heating to customers are created. The use of electric energy for heating buildings, industries and other facilities in commercial activities is improved as the electrical energy is used twice, firstly to perform digital processing and secondly to provide thermal energy which can be used for heating.

According to an aspect of the invention, the cooling agent is a refrigerant/cooling medium comprising air, an inert gas, a gas mixture, or a liquid fluid medium.

According to a further aspect of the invention, fluid media can be in the gaseous and/or the liquid phase.

According to yet a further aspect of the invention, the heating from the solid state thermal energy generator is provided to customers in the vicinity of the solid state thermal energy generator. Thanks to the fact that the heating from solid state thermal energy generators is provided to customers in the vicinity of the solid state thermal energy generator, at the same time as the solid state thermal energy generator produces computing capacity to customers, an energy efficient system and a cost saving improvement for providing heating to customers are created.

According to another aspect of the invention, the customers facilities such as buildings, industries and other facilities for commercial activities are preferably at a typical district heating distance of within a few kilometers from the solid state thermal energy generator or less.

According to yet another aspect of the invention, a solid state thermal energy generator is a computing unit which includes at least one, but preferably a plurality of processors in a cluster, and a heat exchanger unit. Preferably, the system comprises processor clusters in the range of about 3 kW up to 30 kW. A plurality of clusters can be contained in a module housing and the number of clusters in the module housing adapted to the local heating requirements, Increasing the number of clusters in a module housing means that heating levels in the range of thousands of kilowatts can be achieved in a small volume. This results in a system that is cost efficient and can be adapted for any customer, large or small. Heat generated by the processors can be collected by means of the heat exchanger within or adjacent to the computing unit.

According to a further aspect of the invention, the amount of thermal energy generated in the computational core of computers/processors in the solid state thermal energy generators, is controlled by altering the computational load on the core. Hence, it is possible to provide a system that is cost efficient and able to reach large cost savings in the use of electric energy for heating buildings, industries, residential buildings and other facilities.

According to yet a further aspect of the invention, the system has a heated medium pumping system to circulate heated medium to provide heating, and a storage system to store heated medium during low demand periods and to deliver heating using the stored heated medium during peak demand. Thus, the system for providing heating can be very cost efficient.

According to another aspect of the invention, the system, as a by-product, delivers computational power for scientific, industrial, commercial, or private purposes which can be consumed locally or delivered through the internet. Thus, the computing capacity provided in the solid state thermal energy generator can be sold, leased, rented, or put on the market in other ways.

According to yet another aspect of the invention, the computational power is sold on the market using a computer-controlled brokering system. Hence, the system can be cost efficient.

Further, the objects are also achieved by a method, according to the invention, for providing heating to customers in the system.

The objects are also achieved by a use of the system according to the invention, for providing heating from a solid state thermal energy generator to customers, while providing computing capacity.

Further advantages and advantageous features of the invention are disclosed in the following description and in the dependent claims.

### BRIEF DESCRIPTION OF THE DRAWINGS

Below, embodiments of the invention will be described with reference to the drawings, in which:

FIG. 1 shows a computing module comprising a computing unit, a fan unit and a heat exchanger unit according to an embodiment of the invention,

FIG. 2 shows a module housing for solid state thermal energy generator modules having several modules as shown in FIG. 1, and

FIG. 3 shows a wiring diagram for a system providing heating from a plurality of solid state thermal energy generators with three modules as shown in FIGS. 1 and 2, according to an embodiment of the invention.

### DETAILED DESCRIPTION OF EMBODIMENTS OF THE INVENTION

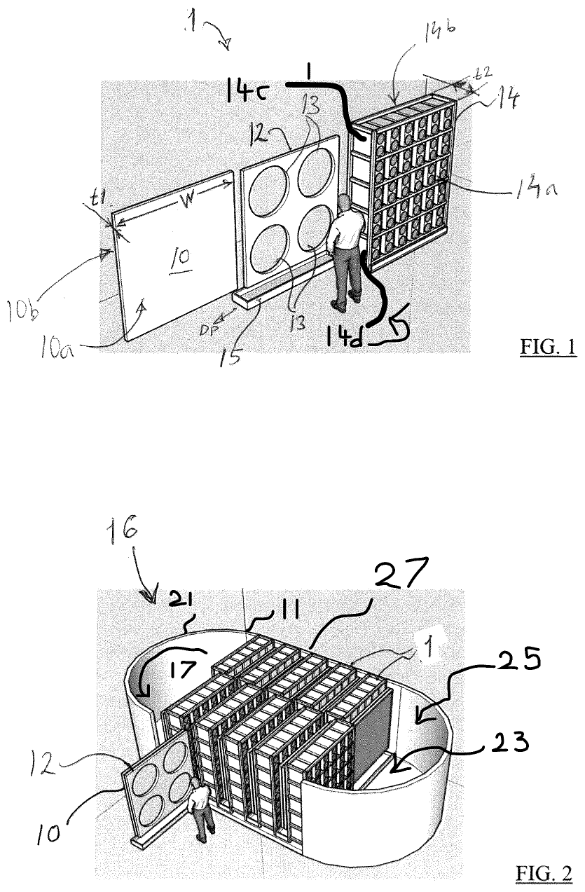

FIG. 1 shows an example of a computing module 1 suitable for use as a solid state “thermal generator”/thermal energy generator (SSTG) according to an embodiment of the invention. The computing module comprises a computing unit 10, an optional cooling agent circulating fan unit 12 which is suitable for circulating cooling agent when gas is used as a cooling agent, and a heat exchanger unit 14 according to an embodiment of the invention. The computing unit 10 is schematically shown as a first quadratic element with a relatively large, front side surface 10a and an opposite corresponding back side surface 10b. The thickness t1 of the first quadratic element may be relatively thin.

The computing unit 10 includes a least one, but preferably a plurality of calculating processors, such as a central processing unit (CPU), microprocessors or a graphics processing unit (GPU) etc. These convert electrical energy into thermal energy when they operate. Basically, according to the present invention, any solid state processors can be used for generating heating or providing computing capacity. However, for efficient space management, it is preferred to use processor clusters in the range of about 1 kW up to installed electrical power, suitably processor clusters in the range of about 3 kW up to 30 kW. It is optimal to have the SSTG as close as possible to a consumer of heating, that make it possible to adopt present and existing infrastructure.

A first quadratic element for use with the present invention may be of any suitable size, for example, from a relatively small quadratic element having a length L and width W of about 1×1 m up to larger quadratic element of about 5×5 m. Smaller and larger dimensions are also possible. Preferably a length L and width W of a first quadratic element used with the present invention, as illustrated in FIG. 1, can be about 3×3 m. The thickness t1 of the first quadratic element can be relatively thin, from about 5 cm up to about 50 cm. Preferably the thickness t1 of the first quadratic element used with the present invention, as illustrated in FIG. 1, can be from about 5 cm up to about 15 cm.

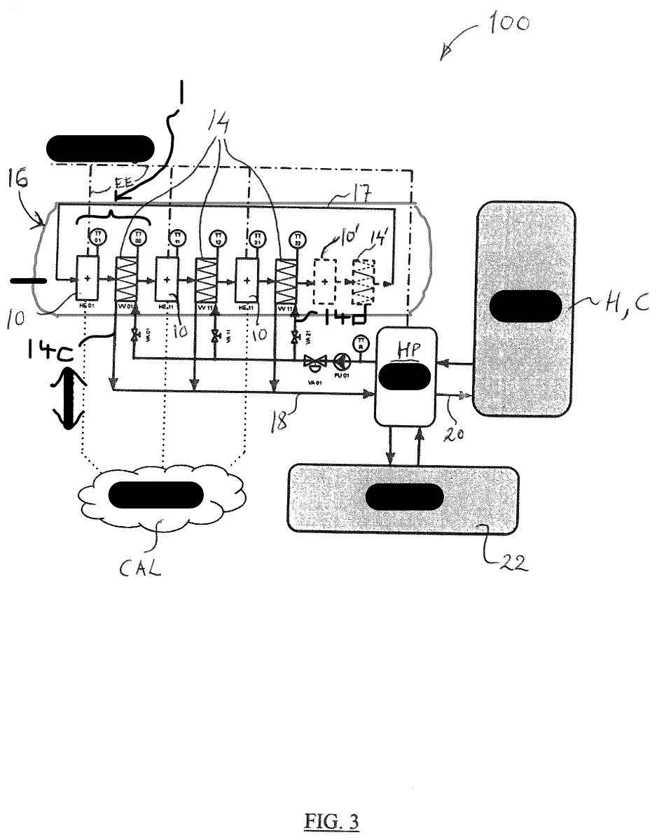

Preferably, the computing module 1 may be provided in a module housing 16 (as shown in FIG. 2) adapted to be the size a standard sized container having dimensions of H 2438 mm×W 2 591 mm ISO container size for shipping, 20 ft or 40 ft, thus allowing transportation by container transporting systems. The module housing 16 forms a fluid tight enclosure 27 for computing modules 1. Module housings having dimensions which are adapted to integral fractions of these sizes may also be provided so that an integral number of module housing can be fitted into the space of a single container without wasting any space. Slightly smaller modules (e.g., ten to fifteen centimetres shorter, narrower, and/or lower) which can be fitted inside a container for transportation or use are also envisaged.

Smaller modules having a footprint equal to a standard shipping pallet, e.g., 1200×1000 mm, 1165×1165 mm (45.9×45.9 inches), 1067×1067 mm (42×42 inches) or 1219×1016 (48×40 inches) may also be provided. Preferably module housings are thermally insulated to minimise the loss of heat energy to the surrounding. Thermal insulating material 21 can be provided (internally and/or externally) on all exposed surfaces of the modular unit. The thermal energy from inside the module unit can be transferred to places where it is needed by, preferably insulated, pipes or ducts.

Further, the optional cooling agent circulating fan unit 12 is schematically shown as a second quadratic element with a relatively large front side surface and an opposite corresponding back side surface. The thickness of the second quadratic element may be relatively thin compared to the first quadratic element. Preferably the dimensions of the second quadratic element of the fan unit 12 used with the present invention, as illustrated in FIG. 1, have about the same dimensions as the first quadratic element of the computing unit 10 as described above, so that the fan unit can supply cooling agent to (or receive cooling agent from) substantially the whole of the surface of the computing unit which is faces.

As further shown in FIG. 1, the fan unit 12 may comprise of at least four fan devices as schematically illustrated by the circular recesses 13 in FIG. 1. However, the number of fan devices for each fan unit may be less than four or greater than four.

When the cooling agent is a liquid cooling agent, then individual fan units can be replaced by one or more liquid cooling agent circulation pumps.

Yet further, the heat exchanger unit 14 is schematically shown as a third quadratic element with a relatively large front side surface 14a and an opposite corresponding back side surface 14b. The thickness t2 of the third quadratic element may be larger than the thickness tl of the first and second quadratic elements of the respectively computing unit 10 and the fan unit 12. The thickness t2 of the third quadratic element used with the present invention, as illustrated in FIG. 1, can be from about 25 cm up to about 100 cm for ISO container-sized modules. Smaller thicknesses t2 such as equal to or greater than 1 cm and less than or equal to 10 cm are suitable for smaller modules, for example pallet-sized units, while thickness t2 equal to or greater than 10 cm and less than or equal to 25 cm are suitable for intermediate-sized modules which are larger than pallet-sized modules and smaller than ISO container-sized modules.

Preferably, the dimensions of the third quadratic element of the heat exchanger used with the present invention, as illustrated in FIG. 1, have about the same dimensions as the first quadratic element of the computing unit 10 as described above, so that the heat exchanger is exposed to cooling agent over substantially the whole of the surface of the heat exchanger.

The heat exchanger may be of any suitable type which exchanges heat energy from a cooling agent flowing across it from the front side surface to the rear side surface to an internal fluid medium which can be heated by the heat exchanger. The fluid medium can then be transported away and used.

The computing module 1 may be arranged in a modular housing 16 as part of an inner closed circuit 17 (see description with reference to FIG. 3 below) for the recirculation of a cooling agent. The cooling agent is preferably air, an inert gas, a gas mixture and/or a liquid medium. The direction of flow may be as shown by the arrow in FIG. 2 where the cooling agent passes though the computing unit 10 before passing though the adjacent heat exchanger, or the flow may be vice versa.

FIG. 2 shows a solid state thermal energy generator (SSTG) module housing 16 having a plurality of computing modules 1, e.g., ten modules, as shown in FIG. 1. However, the number of modules 1 may be more or less than ten, depending on the computing capacity of each module 1 and the local heating requirements. The same reference numerals are used for the corresponding features as shown and described with reference to FIG. 1. The module housing 16 forms a fluid tight enclosure for computing modules 1 with a roof (which is not shown in FIG. 2 for reasons of clarity), a base 23 and a continuous side wall 11 (part of which is omitted in FIG. 2 for reasons of clarity) and forms a fluid-tight container for the modules. Preferably, the wall 11 and base and roof of the module housing is provided with insulation 21.

The inner closed circuit 17 for a cooling agent from one computing unit 10 leads to adjacent inner closed circuits in adjacent solid state thermal energy generator (SSTG) computing units 10, in order to form an endless closed inner circuit when a plurality of solid state thermal energy generator computing units 10 are connected inside a module housing 16 for solid state thermal energy generator (SSTG) computing units 10. The heating produced in the computing units 10 is controlled by varying the computing load of the computing units 10, thus when more heating is required the computing load is increased, thereby generating more waste thermal energy, and when less heating is required the computing load can be decreased (or excess thermal energy can be stored for later use).

In a module housing 16, the heat exchanger units 14 further each comprise an outlet fluid connection 14c to, and an inlet fluid connection 14d from, an outer circuit 18 (see description with reference to FIG. 3 below) in order to form an endless closed outer circuit containing a fluid medium, thus connecting a plurality of heat exchanger units 14 to the outer circuit. Thus, the outlet and inlet connectors are in fluid connection to the exterior of the heating module housing. The fluid connections to and from the closed outer circuit made directly to the closed outer circuit or to a header connected to the closed outer circuit. The heat exchangers are conventional and have substrates with input heat conducting surfaces exposed to the cooling agent at a temperature Ta in the module housing and output heat conducting surfaces exposed to the fluid medium at a lower temperature Tf from the outer closed circuit. The heat exchangers thereby transfer heat energy inputted on the input side by the cooling agent (which is thereby cooled to a temperature Tc which is lower than Ta) to the fluid medium on the output side, thereby raising its temperature to a temperature Tr which is greater than Tf. The outer closed circuit 18 delivers the heated fluid medium, preferably via a heat pump HP (see description with reference to FIG. 3 below), or via a simple circulation pump arrangement, to the customer and/or to a thermal energy storage system, and returns cooled fluid medium at temperature Tf to the heat exchangers. Using a heat pump enables the system to elevate the temperature of heating medium provided to a customer which can be used for heating water, space heating or process heating while at the same time producing cooled fluid medium which, in addition to being returned to the heat exchangers, can be used for refrigeration or air conditioning purposes.

Electric energy EE (see description with reference to FIG. 3 below) is provided to the heat pump and/or circulation pump arrangement as well as the computing units 10 and the fan units 12. The computing units 10 provide computing results via a computing flow to a mesh (network) for computing calculations CAL (see description with reference to FIG. 3 below).

As mentioned above, the heat energy in the inner closed circuit 17 is exchanged to a fluid medium in the outer circuit 18 via the heat exchanger units 14. The fluid medium can be either a gas such as air or a liquid phase such as water or another liquid. Each heat exchanger thereby cools down the cooling agent in the inner circuit and thus provides cooled cooling agent for reducing the inner temperature (i.e., by absorbing waste heat) of the next computing unit 10. The rate and/or amount of heat energy transferred from the inner circuit to the outer circuit can be regulated by controlling the flow rate of the fluid medium in the outer circuit.

Preferably, the dimensions of the third quadratic element of a heat exchanger unit 14 used with the present invention, as illustrated in FIG. 1, have about the same length and width dimensions as the first and second quadratic element of the respectively computing unit 10 and the fan unit 12 as described above.

Preferably, the computing unit 10 and any fan unit 12 are supported at the lower portions on a displaceable foot support 15 which can be moved laterally in a direction to and from the heat exchanger unit, e.g., they can be slid in and out of a module housing. Hence, the computing unit 10 and any fan unit 12 are displaceably arranged with respect to the heat exchanger unit 14, via a displaceable foot support as shown in FIG. 2 and can be removed from housing module without moving the heat exchanger, thereby enabling easy replacement or service of these units without disturbing the heat exchanger. When positioned in the module, housing seals prevent the leakage of cooling agent from the interfaces of the foot supports 15 and the wall 11, roof and base 23 of the module housing. Preferably, the computing unit 10 and any fan unit 12 are displaceably arranged relative each other on the foot support 15 as shown in FIG. 1 above, thereby permitting maintenance or replacement of the computing unit or fan unit without disturbing the other unit. Hence, as shown in FIG. 1, the computing unit 10 and a fan unit 12 have been displaced into a position away DP from the heat exchanger unit 14 for repair or service or replacement.

FIG. 3 shows schematically a wiring and fluid connection for a system 100 providing heating from a solid state thermal energy generator (SSTG) module housing 16 with three computing each modules 1, comprising a computing unit 10, a fan unit 12 (see FIGS. 1-2; not illustrated in FIG. 3) and a heat exchanger unit 14, as shown in FIGS. 1 and 2, according to an embodiment of the invention. Preferably, the modules 1 are comprised in a fluid-tight module housing 16 with conventional fluid couplings and electrical connectors (not shown) allowing the transfer of heated medium and electricity to and from the interior of the module housing. The same reference numerals are used for the corresponding features as shown and described with reference to FIG. 1. Data can be sent to and from the computing units 10 to a network CAL as shown by dotted lines in the figure. There can be any number of modules 1, as illustrated in FIG. 3, by a further computing unit 10′ and a heat exchanger unit 14′. The module housing 16 can be seen as a ring-formed arrangement, a donut/torus or rectangular with straight sides and curved ends (as shown in FIG. 2) or straight sides and ends or the like, whereby the cooling agent passing through each layer of computing modules 1 absorbs waste heat from the computing unit 10, delivers the waste heat to a heat exchanger 14 when the cooling agent is cooled by the extraction of the heat energy into the heat exchanger before flowing to a further computing unit 10. In the module housing 16 shown in FIG. 2, if the cooling agent is a liquid, then one or more cooling liquid circulation pumps can be provided in the curved volumes 25 at the ends of the module housing.

The system 100 of FIG. 3 generates heating H to customers C from the solid state thermal energy generator module housing 16 having at least three modules 1, comprising a computing unit 10, a fan unit 12 and a heat exchanger unit 14. The computing units 10 perform computer-based calculations CAL that generate heat energy from the electrical energy used by the computing units. This heat energy is removed from the computing units by the circulating cooling agent. The closed module housing 10 further comprises an inner closed circuit for recirculation of the cooling agent. The heat energy in the inner closed circuit 17 is exchanged from the heat exchangers 14 to a fluid medium in an outer circuit 18 via the heat exchangers 14 that are positioned to receive the heat energy in the inner closed circuit 17. The heated fluid medium in the outer circuit is supplied via a conduit 20 to customers for immediate consumption and/or to be stored in a heating storage 22 and/or be dumped to the environment, thus forming cooled fluid medium. This cooled fluid medium is returned to the heat exchangers where it is heated-up again by the waste heat energy taken from the computing units, thereby extracting heat energy from the cooling agent within the module housing.

As mentioned above, electric energy EE is provided to a pump for circulating fluid medium (which could be a heat pump HP) as well as to the computing units 10 and the fan units 14. The computing units 10 provide computing results via a computing flow to the mesh (network) for calculations CAL.

The heating H from the solid state thermal energy generator (SSTG) module housing 16 is provided to customers C in the vicinity of the solid state thermal energy generator (SSTG) module housing 16. In the system 100 according to the invention, the customers facilities such as buildings, industries and other facilities for commercial activities are preferably at a typical district heating distance from the solid state thermal energy generator (SSTG) 16 or less.

The system 100 generate heating H for residential, commercial or industrial heating purposes (and cooling capacity if a heat pump is provided) which can be used for climate control of buildings and facilities as well as heating needed for industrial processes. The primary energy source for the heating is electricity which powers a computational device, that generates heating through resistance and inductive voltage drops.

The heating is provided by thermal energy transferred from the solid state thermal energy generators (SSTG), that is the computational core of computers/processors in the computing units 10, by heat-conductors (for example cooling fins or the like) transferring the thermal energy to a transfer fluid, the cooling agent, which can be liquid or gas inside the module housing. The amount of heating power (i.e., thermal energy) generated in the module housing is controlled by altering the computational load on the core.

Preferably, the computing capacity load is controlled through a SSTG management system. This reduces or increases the amount of computing taking place within the module housing as the requirement for heating raised or lowers. In the event that computing capacity demand is higher than the heating demand, then the excess heat from the module housing can be dumped externally or used to increase the thermal energy stored in the heating storage or it can be used in another external system.

The computing algorithms can be any type which is suitable for the type of solid state thermal energy generator (SSTG) in the system, including software defined algorithms or file program arrays. Even when on standby, solid state computing units convert electrical energy into thermal energy and the temperature of the computing units is controlled by controlling the cooling fluid mass flow, i.e., by controlling the cooling agent pump speed. As a byproduct, the system 100 delivers computational power for scientific, industrial, commercial or private purposes which can be consumed locally or delivered through the internet. The computational power is sold on the market using a computer controlled brokering system.

Preferably the system 100 may have an outer circuit fluid medium pumping and storage system 22 to store heat energy from the heated fluid medium in the outer circuit during low demand periods and deliver heat energy to the fluid medium in the outer circuit during peak demand if the peak demand is greater than the supply of heat available from the solid state heating system. The storage scheduling and system control is preferably controlled with a computer with a manual backup panel.

The system 100 preferably has safety functions as part of the solid state thermal energy generator (SSTG) management system, in order to prevent core overheating by lowering computational load in the case of core coolant exit temperature exceeded the design maximum.

For instance, the safety functions can be thermocouples and sensors monitoring each solid state thermal energy generator (SSTG) and/or monitoring the temperature of the cooling agent.

The system can have a fuel powered heat or electrical energy source as backup, which is started in case of electrical grid failure.

It is to be understood that the present invention is not limited to the embodiments described above and illustrated in the drawings; rather, the skilled person will recognize that many changes and modifications may be made within the scope of the appended claims.

1-13. (canceled)

14. A system for providing heating to customers from a solid state thermal energy generator module housing characterized in that the module housing comprises a cooling agent and a plurality of solid state computing modules wherein each computing module comprise a computing unit provided with processors and a heat exchanger unit, the computing unit being adapted to provide computing capacity and generate thermal energy transferable to the cooling agent, and the heat exchanger unit being adapted to remove thermal energy from the cooling agent,
wherein the module housing further comprises an inner closed circuit for recirculation of the cooling agent through said heat exchanger units,
wherein the heat exchangers are adapted to exchange thermal energy to a fluid medium in an outer circuit.

15. A system according to claim 14, wherein the heated fluid medium is connected via a conduit to customers and/or to heating storage system.

16. The system according to claim 14, wherein the cooling agent is a refrigerant or cooling medium comprising air, an inert gas, a gas mixture or a fluid medium.

17. The system according to claim 14, wherein each computing unit comprises a plurality of processors.

18. The system according to claim 19, wherein the computing units each have power consumption in the range equal to or greater than 3 kW to less than or equal to 30 kW.

19. The system according to claim 14, wherein the amount of thermal energy provided to the fluid medium in the outer circuit is controllable by altering the computational load in the computing units.

20. The system according to claim 14, wherein the system has a heat pumping and storage system to store thermal energy during low demand periods and deliver heating during peak demand.

21. The system according to claim 14, wherein the computational power is sold on the market using a computer controlled brokering system.

22. A method for providing heating to customers in a system according to claim 14, wherein the method comprises the steps of:
producing heating by the computing unit;
exchanging the heat energy in the inner closed circuit to a fluid medium in an outer circuit via the heat exchanger that is positioned to receive the heat energy in the inner closed circuit,
wherein the heated fluid medium is supplied via a conduit to customers for immediate consumption, to be stored in a heating storage system or be dumped.

23. A use of a system according to claim 14, for providing heating from a solid state thermal energy generator to customers in the vicinity of the solid state thermal energy generator, while providing computing capacity.

24. Module housing for a heating system according to claim 14, wherein the module housing comprises a cooling agent and a plurality of solid state computing modules, each module comprising a computing unit provided with computing processors and a heat exchanger unit, the computing unit being adapted to provide computing capacity and generate thermal energy transferable to the cooling agent and the heat exchanger unit being adapted to remove heat from the cooling agent, wherein the module housing further comprises an inner closed circuit for recirculation of the cooling agent through said heat exchanger units wherein said heat exchangers have fluid inlet and outlet connections which are in fluid connection to the exterior of the module housing.

25. Module housing according to claim 24, wherein module housing forms a fluid-tight enclosure for the cooling agent and solid state computing modules.

26. Module housing according to claim 25, characterized in that the fluid-tight enclosure is thermally insulated.
